(19) United States
(12) Patent Application Publication
(10) Pub. No.: US 2026/0268836 A1
(43) Pub. Date: Sep. 10, 2026

(54) MICRO-DISPLAY SYSTEM, MICRO-DISPLAY PANEL AND WEAK PULL-UP/PULL-DOWN CIRCUIT

(71) Applicant: Hue Inc., Shanghai (CN)

(72) Inventors: Chunming Li, Shanghai (CN); Mengqian ZOU, Shanghai (CN); Jing Ju, Shanghai (CN); Hongyun Liu, Shanghai (CN)

(73) Assignee: Hue Inc., Shanghai (CN)

(21) Appl. No.: 19/558,305

(22) Filed: Mar. 5, 2026

(30) Foreign Application Priority Data
Mar. 7, 2025 (CN) 202510270295.2

(51) Int. Cl. G09G 3/32; G06F 3/14; G09G 3/20; H10H 29/855

(52) U.S. Cl. CPC G09G 3/32; G06F 3/1446; G09G 3/2096; G09G 2300/023; G09G 2320/0233; H10H 29/855

(57) ABSTRACT

A micro-display system comprises a shared transmission line and a plurality of micro-display panels. Each panel includes: a flag lead configured to transmit signals to a host when driven to a high level; a PMOS transistor connected with the flag lead to drive the flag lead to the high level when conducting; a pull-down resistor grounded at one end and connected to the flag lead at the other end to pull the flag lead to a low level when the PMOS transistor is not conducting; and a signal circuit module. The signal circuit module generates a control signal upon receiving a turn-on instruction from the host, and sends a low level signal to conduct the PMOS transistor when generating a flag signal. The shared transmission line connects the host to the flag leads of the plurality of micro-display panels.

### CROSS-REFERENCE TO RELATED APPLICATION

This application claims the priority benefit of China application serial no. 202510270295.2, filed on Mar. 7, 2025. The entirety of the above-mentioned patent application is hereby incorporated by reference herein and made a part of this specification.

### BACKGROUND

### Technical Field

The present disclosure relates to the field of micro-LED technology, and particularly relates to a micro-display system and a weak pull-up/pull-down circuit.

### Description of Related Art

Micro light emitting diode (Micro-LED) is an emerging display technology, which miniaturizes traditional LEDs to make their size to micrometer-level, and as small-sized and luminescent semiconductor components, micro-LED devices have advantages such as low power consumption, long lifespan, high brightness, and high contrast ratio, etc.

Currently, micro-LEDs are limited by process conditions and color panels cannot be mass produced, the existing micro-display panels composed of micro-LED arrays are typically monochromatic, i.e., they can only emit light of one color. If it is needed to display color images, then three micro-display panels capable of emitting different colors of light need to be assembled together for use, i.e., a red light micro-display panel, a green light micro-display panel, and a blue light micro-display panel are assembled to form a micro-display system.

In practical use, the existing micro-display systems cannot return the flag signals inside the micro-display panel to the host, or even if the flag signals can be returned, they occupy a relatively large number of host leads, because the three micro-display panels need to return the flag signals to the host through separate connection lines, which also increases the number of connection lines.

### SUMMARY

In order to solve at least some of the aforementioned issues in the prior art, the task of the present disclosure is to provide a micro-display system, which includes:

a plurality of micro-display panels, each including:

a flag lead configured to transmit signals to a host when the flag lead is driven to a high level;

a PMOS transistor connected with the flag lead, wherein the PMOS transistor is configured to drive the flag lead to the high level when the PMOS transistor is conducting;

a pull-down resistor, having a first terminal connected with the flag lead and a second terminal grounded, wherein the pull-down resistor is configured to pull the flag lead down to a low level when the PMOS transistor is not conducting; and

a signal circuit module connected with the PMOS transistor, and configured to generate a high level control signal upon receiving a turn-on instruction from the host, and to send a low level signal to the PMOS transistor when generating a flag signal, such that the PMOS transistor conducts; and

a shared transmission line connecting the host with the flag leads of the plurality of micro-display panels.

Furthermore, the PMOS transistor has a source connected with a power supply inside each of the plurality of micro-display panels, a drain is connected with the flag lead, and a gate is connected with the signal circuit module.

Furthermore, the drain of the PMOS transistor is further connected with the pull-down resistor.

Furthermore, the signal circuit module includes:

a flag signal input terminal; and

an inverter connected between the flag signal input terminal and the PMOS transistor.

Furthermore, the flag signal input terminal includes:

a plurality of flag signal generation modules configured to generate flag signals;

a plurality of control signal generation modules configured to generate control signals to control whether the flag signals generated by the flag signal generation modules are output;

a plurality of AND gate modules, wherein input terminals of the plurality of AND gate modules are connected with at least one flag signal generation module and at least one control signal generation module; and

an OR gate module group, having an input terminal connected with the output terminals of the plurality of AND gate modules, and an output terminal is connected with the inverter.

Furthermore, the plurality of flag signal generation modules include: a row scan timing flag signal generation module, a first global scan timing flag signal generation module, a second global scan timing flag signal generation module, a DSI processing module interrupt signal generation module, and a DSI interrupt signal generation module; and

the plurality of control signal generation modules include a first control signal generation module, a second control signal generation module, a third control signal generation module, a fourth control signal generation module, and a fifth control signal generation module.

Furthermore, the plurality of AND gate modules include a first AND gate module, a second AND gate module, a third AND gate module, a fourth AND gate module, and a fifth AND gate module, wherein:

the first input terminal of the first AND gate module is connected with the row scan timing flag signal generation module, and the second input terminal of the first AND gate module is connected with the first control signal generation module;

the first input terminal of the second AND gate module is connected with the first global scan timing flag signal generation module, and the second input terminal of the second AND gate module is connected with the second control signal generation module;

the first input terminal of the third AND gate module is connected with the second global scan timing flag signal generation module, and the second input terminal of the third AND gate module is connected with the third control signal generation module;

the first input terminal of the fourth AND gate module is connected with the DSI processing module interrupt signal generation module, and the second input terminal of the fourth AND gate module is connected with the third control signal generation module; and

the first input terminal of the fifth AND gate module is connected with the DSI interrupt signal generation module, and the second input terminal of the fifth AND gate module is connected with the third control signal generation module.

Furthermore, the OR gate module group includes:

a first OR gate module, its first input terminal, second input terminal, and third input terminal are connected with the output terminals of the first AND gate module, the second AND gate module, and the third AND gate module, respectively;

a second OR gate module, its first input terminal and second input terminal are connected with the output terminals of the fourth AND gate module and the fifth AND gate module; and

a third OR gate module, its first input terminal and second input terminal are connected with the output terminals of the first OR gate module and the second OR gate module, respectively, and its output is connected with the input terminal of the inverter.

Furthermore, the micro-display panel further includes a register connected with the pull-down resistor and configured to control the turn-on and -off of the pull-down resistor.

Furthermore, the micro-display panel further includes a communication interface connected with the host, the signal circuit module, and the register.

Furthermore, the shared transmission line has one end connected with a lead of the host and another end connected with the flag leads of the plurality of micro-display panels.

Furthermore, the control signal generation module generates a high level control signal;

the flag signal generation module generates a high level flag signal.

Furthermore, the ratio of the resistance value of the pull-down resistor to the equivalent resistance value of the PMOS transistor is set such that the difference between the high level and low level of the flag lead is less than or equal to 50% of the high level.

Furthermore, the pull-down resistor is a weak pull-down resistor of 1kΩ-500kΩ.

Furthermore, the plurality of micro-display panels include a red light micro-display panel, a green light micro-display panel, and a blue light micro-display panel.

The present disclosure also provides a micro-display system, which includes:

a plurality of micro-display panels, each including:

a flag lead configured to transmit signals to a host when the flag lead is pulled down to a low level;

an NMOS transistor connected with the flag lead, wherein the NMOS transistor is configured to pull the flag lead down to the low level when the NMOS transistor is conducting;

a pull-up resistor having a first terminal connected with the flag lead and a second terminal connected with a power supply inside each of the plurality of micro-display panels, wherein the pull-up resistor is configured to pull the flag lead up to a high level when the NMOS transistor is not conducting; and

a flag signal input terminal connected with the NMOS transistor, and configured to generate a high level control signal upon receiving a turn-on instruction from the host, and to send a high level signal to the NMOS transistor when generating a flag signal, such that the NMOS transistor conducts; and

a shared transmission line connecting the host with the flag leads of the plurality of micro-display panels.

Furthermore, the NMOS transistor has a source grounded, a drain connected with the flag lead, and a gate connected with the flag signal input terminal.

Furthermore, the drain of the NMOS transistor is further connected with the pull-up resistor.

Furthermore, the flag signal input terminal includes:

a plurality of flag signal generation modules configured to generate flag signals;

a plurality of control signal generation modules configured to generate control signals to control whether the flag signals generated by the flag signal generation modules are output;

a plurality of AND gate modules, wherein input terminals of the plurality of AND gate modules are connected with at least one flag signal generation module and at least one control signal generation module; and

an OR gate module group having an input terminal connected with the output terminals of the plurality of AND gate modules and an output terminal connected with the gate of the NMOS transistor.

Furthermore, the plurality of flag signal generation modules include: a row scan timing flag signal generation module, a first global scan timing flag signal generation module, a second global scan timing flag signal generation module, a DSI processing module interrupt signal generation module, and a DSI interrupt signal generation module; and

the plurality of control signal generation modules include a first control signal generation module, a second control signal generation module, a third control signal generation module, a fourth control signal generation module, and a fifth control signal generation module.

Furthermore, the plurality of AND gate modules include a first AND gate module, a second AND gate module, a third AND gate module, a fourth AND gate module, and a fifth AND gate module, wherein:

the first input terminal of the first AND gate module is connected with the row scan timing flag signal generation module, and the second input terminal of the first AND gate module is connected with the first control signal generation module;

the first input terminal of the second AND gate module is connected with the first global scan timing flag signal generation module, and the second input terminal of the second AND gate module is connected with the second control signal generation module;

the first input terminal of the third AND gate module is connected with the second global scan timing flag signal generation module, and the second input terminal of the third AND gate module is connected with the third control signal generation module;

the first input terminal of the fourth AND gate module is connected with the DSI processing module interrupt signal generation module, and the second input terminal of the fourth AND gate module is connected with the third control signal generation module; and

the first input terminal of the fifth AND gate module is connected with the DSI interrupt signal generation module, and the second input terminal of the fifth AND gate module is connected with the third control signal generation module.

Furthermore, the OR gate module group includes:

a first OR gate module, its first input terminal, second input terminal, and third input terminal are connected with the output terminals of the first AND gate module, the second AND gate module, and the third AND gate module, respectively;

a second OR gate module, its first input terminal and second input terminal are connected with the output terminals of the fourth AND gate module and the fifth AND gate module; and

a third OR gate module, its first input terminal and second input terminal are connected with the output terminals of the first OR gate module and the second OR gate module, respectively, and its output is connected with the gate of the NMOS transistor.

Furthermore, the micro-display panel further includes a register connected with the pull-up resistor and configured to control the turn-on and -off of the pull-up resistor.

Furthermore, the micro-display panel further includes a communication interface connected with the host, the flag signal input terminal, and the register.

Furthermore, the shared transmission line has one end connected with a lead of the host and another end connected with the flag leads of the plurality of micro-display panels.

Furthermore, the control signal generation module generates a control signal of high level;

the flag signal generation module generates a flag signal of high level.

Furthermore, the ratio of the resistance value of the pull-up resistor to the equivalent resistance value of the NMOS transistor is set such that the difference between the high level and low level of the flag lead is less than or equal to 50% of the high level.

Furthermore, the pull-up resistor is a weak pull-up resistor of 1kΩ-500kΩ.

Furthermore, the plurality of micro-display panels include a red light micro-display panel, a green light micro-display panel, and a blue light micro-display panel.

Furthermore, the micro-display panel includes:

a drive backplane; and

a plurality of micro-LEDs arranged in an array on the drive backplane.

Furthermore, the micro-LED includes:

an epitaxial layer;

a top conductive layer, the top conductive layer is located on the side surface and top surface of a light-emitting mesa; and

a passivation isolation layer, the passivation isolation layer at least partially covers the side surface of the epitaxial layer, and the passivation isolation layer is located between the epitaxial layer and the top conductive layer.

Furthermore, the micro-LED chip further includes: a current expansion structure located between the micro-LEDs, wherein the current expansion structure is arranged to surround the micro-LEDs, and the current expansion structure is configured to electrically contact the micro-LEDs and at least partially reflect light emitted by the micro-LEDs.

Furthermore, the micro-LED chip further includes microlenses, which are arranged above the micro-LEDs, and adjacent microlenses are connected.

The present disclosure also provides a weak pull-up/pull-down circuit, which includes:

an MOS transistor having a gate connected with a flag signal input terminal, wherein a first electrode selected from a drain and a source of the MOS transistor is connected with a first voltage source, and a second electrode selected from the drain and the source is connected with a first terminal of a pull-up/pull-down resistor;

a pull-up/pull-down resistor having a second terminal connected to a second voltage source, wherein the pull-up/pull-down resistor is configured to be turned on and off by a register signal; and

a flag lead connected with the second electrode of the MOS transistor and the first terminal of the pull-up/pull-down resistor.

Furthermore, the MOS transistor includes a PMOS.

Furthermore, the MOS transistor includes an NMOS.

Furthermore, the weak pull-up/pull-down circuit further includes:

an inverter connected between the flag signal input and the PMOS transistor.

Furthermore, the first voltage source is a power supply, and the second voltage source is ground; or

the second voltage source is a power supply, and the first voltage source is ground.

Furthermore, the ratio of the resistance value of the pull-up/pull-down resistor to the equivalent resistance value of the MOS transistor is set such that the difference between the high level and low level of the flag lead is less than or equal to 50% of the high level.

The present disclosure also provides a micro-display panel including the aforementioned weak pull-up/pull-down circuit.

The present disclosure has at least the following beneficial effects:

The present disclosure provides PMOS transistors and pull-down resistors (or NMOS transistors and pull-up resistors) connected with flag leads inside a plurality of micro-display panels, and the PMOS transistors (or NMOS transistors) are connected with the flag signal input terminal, and the host can flexibly control a certain returned flag signal in a plurality of micro-display panels by controlling whether the PMOS transistors (or NMOS transistors) conduct, such that only a single shared transmission line is needed between the host and the flag leads of a plurality of micro-display panels to meet the requirements of a plurality of micro-display panels to return flag signals to the host, and the occupation of host leads and the number of transmission lines are reduced.

### BRIEF DESCRIPTION OF THE DRAWINGS

In order to further explain the above and other advantages and features of various embodiments of the present disclosure, a more specific description of various embodiments of the present disclosure will be provided with reference to the accompanying drawings. It can be appreciated that these accompanying drawings depict only typical embodiments of the present disclosure, and therefore will not be construed as limiting their scope. In the accompanying drawings, identical or corresponding parts will be indicated by the same or similar reference numerals for the sake of clarity.

FIG. 1 illustrates a schematic diagram of the connection relationship between three existing micro-display panels and a host;

FIG. 2 illustrates a schematic diagram of the micro-display system according to the first embodiment of the present disclosure;

FIG. 3 illustrates the internal circuit of the micro-display panel according to the first embodiment of the present disclosure;

FIG. 4 illustrates the circuit diagram for transmitting the flag signal within the micro-display panel according to the first embodiment of the present disclosure;

FIG. 5 illustrates the internal circuit of the micro-display panel according to the second embodiment of the present disclosure; and

FIG. 6 illustrates the circuit including the flag signal input terminal within the micro-display panel according to the second embodiment of the present disclosure.

### DESCRIPTION OF THE EMBODIMENTS

It should be noted that various components in the accompanying drawings may be exaggerated for the purpose of illustrative illustration and are not necessarily true to scale.

In the present disclosure, the embodiments are merely intended to illustrate the scheme of the present disclosure and should not be construed as limiting.

In the present disclosure, the quantifiers "a" and "one" do not exclude scenarios with multiple elements, unless otherwise specified.

It should also be noted herein that in embodiments of the present disclosure, only a part of the components or assemblies may be shown for the sake of clarity and simplicity, but those ordinary skilled in the art will be able to understand that the required components or assemblies may be added as needed according to specific scenarios in light of the teachings of the present disclosure.

It should also be noted that, within the scope of the present disclosure, the terms "the same", "equal", "equal to", etc. do not mean that the two numerical values are absolutely equal, but rather allow for a certain reasonable error, that is to say, the terms also cover "substantially the same ", "substantially equal" and "substantially equal to".

It should also be noted herein that in the description of the present disclosure, orientations or positional relationships indicated by terms such as "center", "longitudinal", "transverse", "up", "down", "front", "rear", "left", "right", "vertical", "horizontal", "top", "bottom", "inner", "outer", etc., are based on the orientations or positional relationships shown in the accompanying drawings, these terms are only for the purpose of facilitating the description of the present disclosure and simplifying the description, rather than explicitly or implicitly indicating that the devices or elements referred to must have a specific orientation, be constructed in a specific orientation, or operate in a specific orientation, therefore, they should not be construed as limitations on the present disclosure. Furthermore, the terms "first" and "second" are used only for descriptive purposes and should not be construed as explicitly or implicitly indicating relative importance.

Furthermore, the embodiments of the present disclosure describe the process steps in a specific order, however, this is only for the purpose of illustrating the specific embodiment, rather than limiting the order of the steps, and in different embodiments of the present disclosure, the order of the steps can be modified according to the adjustment of the process.

In the present disclosure, the term "configure" refers to the setting of the shape, structure, material, and/or function of a target object to achieve a desired technical effect, and "configure" includes various alternative technical means to achieve this technical effect, which become apparent under the teachings of the present disclosure.

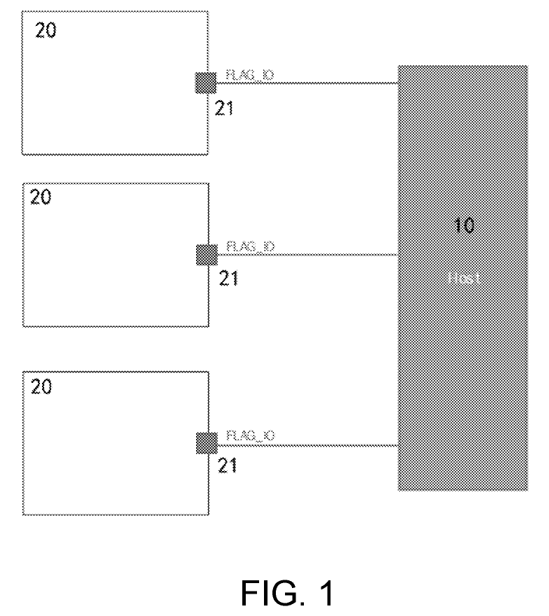

FIG. 1 illustrates a schematic diagram of the connection relationship between three existing micro-display panels and a host.

The existing micro-display system includes a host 10 and three micro-display panels 20, and the flag leads (FLAG_IO) 21 of the three micro-display panels are connected with the host 10 through a connection line, respectively, which occupies three leads of the host 10. When one of the three micro-display panels 20 returns a flag signal to the host 10, it will output a high electric potential with a current of approximately 20 mA, and the other two micro-display panels output a low electric potential with a current of approximately 20 mA. If one connection line is used to connect the flag leads 21 of three micro-display panels 20 and a lead of the host 10, then the output electric potentials of the three micro-display panels 20 are different, which will damage the leads of the micro-display panels 20. The lead of the micro-display panel 20 returning the flag signal to the host 10 is in a high level state, the leads of the other micro-display panels 20 are in a low level state, and a path is formed between the high level output lead and the low level output leads, which will cause a large current to flow out from the leads of the micro-display panel 20, thereby damaging the leads. Therefore, three different connection lines are required to connect the three micro-display panels 20 and the host 10. This will occupy a relatively large number of leads on the host 10 and the number of connection lines is more.

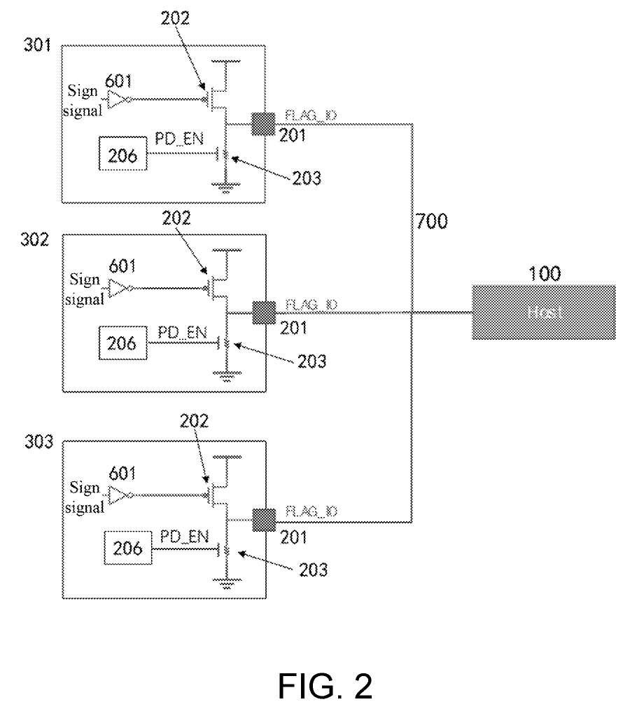

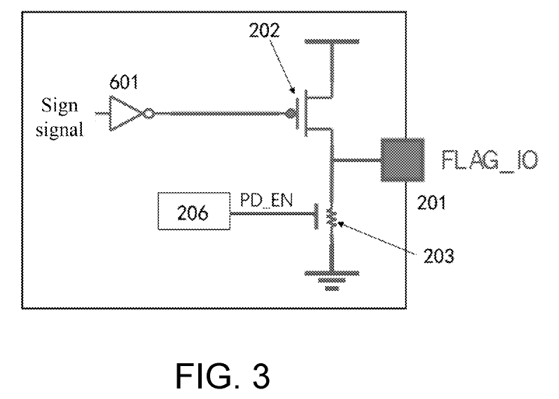

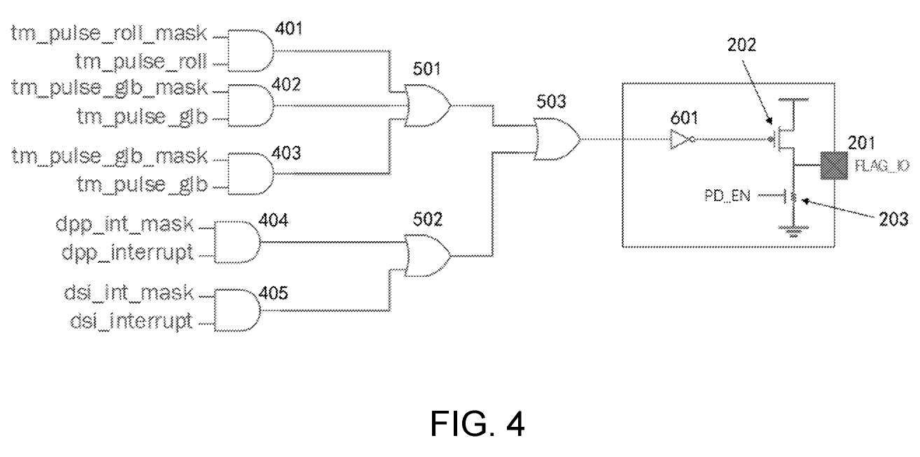

FIG. 2 illustrates a schematic diagram of the micro-display system according to the first embodiment of the present disclosure; FIG. 3 illustrates the internal circuit of the micro-display panel according to the first embodiment of the present disclosure; FIG. 4 illustrates the circuit diagram for transmitting the flag signal within the micro-display panel according to the first embodiment of the present disclosure.

As shown in FIG. 2, a micro-display system includes a plurality of micro-display panels and a host 100. As shown in FIGS. 2 and 3, a micro-display panel includes a flag lead 201, a PMOS transistor 202, and a pull-down resistor 203.

In some embodiments, a plurality of micro-display panels include a red light micro-display panel 301, a green light micro-display panel 302, and a blue light micro-display panel 303.

In some embodiments, the flag leads 201 of the plurality of micro-display panels are connected with leads of the host 100 through a single shared transmission line 700. The flag leads 201 transmit signals to the host 100 when the flag leads 201 are driven to a high level.

In some embodiments, the source (S electrode) of the PMOS transistor 202 is connected with the power supply inside the micro-display panel, and the gate (G electrode) is connected with the signal circuit module inside the micro-display panel, and the drain (D electrode) is connected with the flag lead 201 and a pull-down resistor 203. The PMOS transistor is configured to drive the flag lead 201 to a high level when the PMOS transistor is conducting.

In some embodiments, the signal circuit module includes a flag signal input terminal and an inverter 601. The inverter 601 is connected between the flag signal input terminal and the gate of the PMOS transistor 202. The signal circuit module is configured to generate a high level control signal upon receiving a turn-on instruction from the host 100, and to send a low level signal to the PMOS transistor 202 when generating the flag signal, such that the PMOS transistor 202 conducts.

In some embodiments, a first terminal of the pull-down resistor 203 is connected with the flag lead 201 and the PMOS transistor 202, and a second terminal is grounded. The pull-down resistor 203 is configured to pull the flag lead 201 down to a low level when the PMOS transistor 202 is not conducting.

In some embodiments, the ratio of the resistance value of the pull-down resistor 203 to the equivalent resistance value of the PMOS transistor 202 is set such that the difference between the high level and the low level of the flag lead is less than or equal to 50% of the high level. By adjusting the ratio of the pull-down resistor 203 to the equivalent resistance of the PMOS transistor 202, the level transition of the flag lead becomes relatively gradual, which is conductive to improving the stability and reliability of the circuit.

In some embodiments, the pull-down resistor 203 is a weak pull-down resistor of 1kΩ-500kΩ.

In some embodiments, a register 206 connected with the pull-down resistor 203 is further arranged within the micro-display panel, and the register 206 controls the state of the pull-down resistor 203, i.e., controlling the turn-on and -off of the pull-down resistor 203. When register 206 sends an enable signal (PD_EN) to pull-down resistor 203, the resistor is turned on, which enables pull-down resistor 203 to pull the level of the connected flag lead 201 to a low level.

In the default state, the PMOS transistor 202 is not conducting, and the pull-down resistor 203 is enabled, the state of the flag lead 201 is controlled by the pull-down resistor 203, and the flag lead 201 is in a low level state.

In some embodiments, the plurality of micro-display panels also include communication interfaces (not shown), and the host 100 is connected with the communication interfaces of the plurality of micro-display panels. The communication interfaces are connected with the register 206, and the host 100 can transmit instructions through the communication interfaces to set the register 206, in order to control whether the register 206 sends an enable signal to the pull-down resistor 203. The host can flexibly control whether the pull-down resistor 203 is enabled through the register 206.

In some embodiments, as shown in FIG. 4, the flag signal input terminal includes:

a plurality of flag signal generation modules configured to generate flag signals;

a plurality of control signal generation modules configured to generate control signals to control whether the flag signals generated by the flag signal generation modules are output;

a plurality of AND gate modules, their input terminals are connected with at least one flag signal generation module and at least one control signal generation module; and

an OR gate module group, its input terminal is connected with the output terminals of the plurality of AND gate modules, and its output terminal is connected with the input terminal of the inverter 601.

In some embodiments, the plurality of AND gate modules include a first AND gate module 401, a second AND gate module 402, a third AND gate module 403, a fourth AND gate module 404, and a fifth AND gate module 405.

In some embodiments, the OR gate module group includes a first OR gate module 501, a second OR gate module 502, and a third OR gate module 503.

In some embodiments, the flag signal may be a time flag signal, an interrupt signal, etc.

In some embodiments, the plurality of control signal generation modules include a first control signal generation module, a second control signal generation module, a third control signal generation module, a fourth control signal generation module, and a fifth control signal generation module. The plurality of flag signal generation modules include a row scan timing flag signal generation module, a first global scan timing flag signal generation module, a second global scan timing flag signal generation module, a DSI processing module interrupt signal generation module, and a DSI interrupt signal generation module.

In some embodiments, the first input terminal of the first AND gate module 401 is connected with the row scan timing flag signal generation module to receive the row scan timing flag signal (tm_pulse_roll). The second input terminal of the first AND gate module 401 is connected with the first control signal generation module to receive the first control signal. The first control signal is the control signal (tm_pulse_roll_mask) for the row scan timing flag signal, and the first control signal is set to be active at a high level.

In some embodiments, the output terminal of the first AND gate module 401 is connected with the first input terminal of the first OR gate module 501.

In some embodiments, the first input terminal of the second AND gate module 402 is connected with the first global scan timing flag signal generation module to receive the first global scan timing flag signal (tm_pulse_glb). The second input terminal of the second AND gate module 402 is connected with the second control signal generation module to receive the second control signal. The second control signal is the control signal (tm_pulse_glb_mask) for the first global scan timing flag signal, and the second control signal is set to be active at a high level.

In some embodiments, the output terminal of the second AND gate module 402 is connected with the second input terminal of the first OR gate module 501.

In some embodiments, the first input terminal of the third AND gate module 403 is connected with the second global scan timing flag signal generation module to receive the second global scan timing flag signal (tm_pulse_glb). The second input terminal of the third AND gate module 403 is connected with the third control signal generation module to receive the third control signal. The third control signal is the control signal (tm_pulse_glb_mask) for the second global scan timing flag signal, and the third control signal is set to be active at a high level.

In some embodiments, the output terminal of the third AND gate module 403 is connected with the third input terminal of the first OR gate module 501.

In some embodiments, the output terminal of the first OR gate module 501 is connected with the first input terminal of the third OR gate module 503.

In some embodiments, the first input terminal of the fourth AND gate module 404 is connected with the DSI processing module interrupt signal generation module to receive the DSI processing module interrupt signal (dpp_interrupt). The second input terminal of the fourth AND gate module 404 is connected with the fourth control signal generation module to receive the fourth control signal. The fourth control signal is the control signal (dpp_int_mask) for the DSI processing module interrupt signal, and the fourth control signal is set to be active at a high level

In some embodiments, the output terminal of the fourth AND gate module 404 is connected with the first input terminal of the second OR gate module 502.

In some embodiments, the first input terminal of the fifth AND gate module 405 is connected with the DSI interrupt signal generation module to receive the DSI interrupt signal (dsi_interrupt). The second input terminal of the fifth AND gate module 405 is connected with the fifth control signal generation module to receive the fifth control signal. The fifth control signal is the control signal (dsi_int_mask) for the DSI interrupt signal, and the fifth control signal is set to be active at a high level.

In some embodiments, the output terminal of the fifth AND gate module 405 is connected with the second input terminal of the second OR gate module 502.

In some embodiments, the output terminal of the second OR gate module 502 is connected with the second input terminal of the third OR gate module 503.

In some embodiments, the output terminal of the third OR gate module 503 is connected with the input terminal of the inverter 601.

The control signal generation module controls whether the flag signal is output to the host by generating control signals. When the control signal is set to be active at a high level, the flag signal is output to the host only if a high level control signal is generated, and if the control signal is low level, then the flag signal cannot be output to the host.

When the host 100 requires a certain micro-display panel to return a flag signal, it sends a turn-on instruction to the control signal generation module inside this micro-display panel through the communication interface of this micro-display panel, and after receiving the turn-on instruction, the control signal generation module outputs a valid control signal, and when the corresponding event occurs, the flag signal can be transmitted to the flag lead 201.

In some embodiments, the communication interface is connected with the flag signal input terminal. Furthermore, the communication interface is connected with the first to fifth control signal generation modules, and the first control signal, the second control signal, the third control signal, the fourth control signal, and the fifth control signal are all controlled by the host. When the host requires a certain micro-display panel to return a certain flag signal, the host sends a turn-on instruction to a certain control signal generation module of this micro-display panel through the communication interface, and after receiving the turn-on instruction, the control signal generation module outputs a valid high level control signal, i.e., the control signal is 1. After occurrence of the corresponding event within the micro-display panel, the flag signal generation module outputs a high level flag signal, i.e., the flag signal is 1, and the AND gate module outputs a high level. The OR gate module (the first OR gate module or the second OR gate module) connected with this AND gate module outputs a high level, and the third OR gate module 503 outputs a high level, and the inverter outputs a low level. After receiving the low level signal, the gate voltage of the PMOS transistor 202 connected with the output terminal of the inverter meets the condition for conduction, causing the PMOS transistor 202 to enter a conducting state. The power supply is connected with the flag lead 201 through the conducting PMOS transistor 202, and the level of the flag lead 201 is pulled high and the flag lead 201 is turned to a high level state. The host 100 is connected with the flag lead 201 that is in a high level state, and the input terminal of the host 100 can then detect the high level signal, thereby identifying the corresponding event that has occurred. If the flag lead 201 is in a low level state, then it indicates that no related event has occurred. The host 100 can flexibly select which micro-display panel's flag signal to be output.

Taking the return row scan timing flag signal as an example, the return process of the flag signal is described in detail below.

After receiving the turn-on instruction from the host, the first control signal generation module outputs a high level first control signal. The high level first control signal is input to the first AND gate module 401, and when the row scan timing flag signal is a high level, the first AND gate module 401 outputs a high level, and the first OR gate module 501 outputs a high level; since the first OR gate module 501 is connected with the first input terminal of the third OR gate module 503, the third OR gate module 503 also outputs a high level. The inverter 601 connected with the third OR gate module 503 outputs a low level, and the inverter 601 is connected with the gate of the PMOS transistor, and the PMOS transistor conducts. The conducting PMOS transistor 202 pulls the level of the flag lead 201 high, and the flag lead 201 enters a high level state, and the host 100 detects the high level signal and thereby identifies the corresponding event has occurred, i.e., the micro-display panel has scanned to a designated row in row scan mode.

When the first control signal is in a low level state, the first AND gate module 401 will not output a high level regardless of whether the row scan timing flag signal is in a high level state.

The row scan timing flag signal, the first control signal, the first global scan timing flag signal, the second control signal, the second global scan timing flag signal, the third control signal, the DSI processing module interrupt signal, the fourth control signal, the DSI interrupt signal, and the fifth control signal are described in detail below.

The row scan timing flag signal is primarily used for timing of scan, and when the micro-display panel scans to a designated row in row scan mode, the row scan timing flag signal transitions from a low level to a high level. The first control signal can determine whether the row scan timing flag signal is permitted to output or activated. When the first control signal is in a high level state (tm_pulse_roll_mask=1), the row scan timing flag signal can be normally output to the flag lead.

The functions of the first global scan timing flag signal and the second global scan timing flag signal are the same, and the functions of the second control signal and the third control signal are the same.

The first global scan timing flag signal is primarily used for timing of scan, and when the micro-display panel scans to a designated row in global scan mode, the first global scan timing flag signal transitions from a low level to a high level. The second control signal can determine whether the first global scan timing flag signal is permitted to output or activated. When the second control signal is in a high level state, the first global scan timing flag signal can be normally output to the flag lead.

The display serial interface (DSI) belongs to the MIPI interface. The DSI processing module interrupt signal is an interrupt generated by DSI in the data stream processing module, and when the internal FIFO or state machine is abnormal, this interrupt will be triggered. The internal FIFO (first in first out) is used for temporary storage of data, ensuring orderly transmission and processing of data. When there is an overflow (data write speed exceeding read speed results in data loss) or an underflow (attempting to read data from an empty FIFO) in the FIFO, the dpp_interrupt signal will be triggered. The state machine is responsible for controlling the flow of data processing and state transitions, and when the state machine encounters an abnormality, such as entering an illegal state or being unable to work according to the expected state transition sequence, it will also generate DSI processing module interrupt signals. When the internal FIFO or state machine is abnormal, the DSI processing module interrupt signal transitions from a low level to a high level.

The fourth control signal can determine whether the DSI processing module interrupt signal is permitted to output or activated. When the fourth control signal is in a high level state, the DSI processing module interrupt signal can be normally output to the flag lead.

The DSI interrupt signal is an interrupt generated by the DSI IP module, including the inspection of DPHY and DSI basic protocols and data stream integrity, and it is triggered when there is an abnormality. DPHY is responsible for the physical layer data transmission of DSI, including transmission, reception, level conversion of signal, etc. When the DPHY encounters violations of the DSI basic protocol, such as signal loss, signal errors, or abnormal levels, etc., it will trigger the dsi_interrupt signal. In terms of data flow, when problems such as incomplete data transmission, data errors, data packet loss, and data sequence disorder, etc., occur that affects the integrity of the data flow, it will also cause the DSI IP to generate a DSI interrupt signal.

The fifth control signal can determine whether the DSI interrupt signal is permitted to output or activated. When the fifth control signal is in a high level state, the DSI processing module interrupt signal can be normally output to the flag lead.

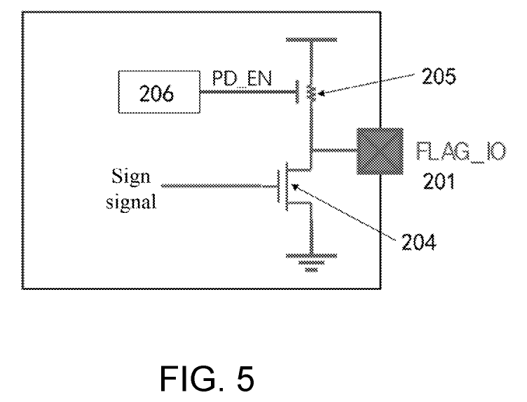

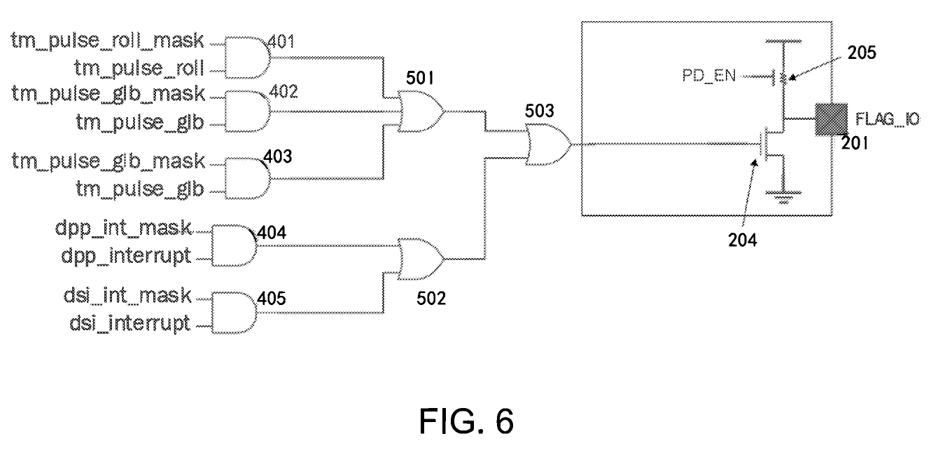

FIG. 5 illustrates the internal circuit of the micro-display panel according to the second embodiment of the present disclosure; FIG. 6 illustrates the circuit including the flag signal input terminal within the micro-display panel according to the second embodiment of the present disclosure.

As shown in FIGS. 5 and 6, the difference between the present embodiment and the first embodiment is that the pull-down resistor and PMOS transistor are replaced with an NMOS transistor 204 and a pull-up resistor 205, and the inverter 601 is removed, and the flag signal input terminal is retained.

In some embodiments, the flag signal input terminal is connected with the gate (G electrode) of the NMOS transistor 204. Furthermore, the third OR gate module 503 of the flag signal input terminal is connected with the gate of the NMOS transistor 204. The flag signal input terminal is configured to generate a high level control signal in the case of receiving a turn-on instruction from the host and to send a high level signal to the NMOS transistor 204 when generating the flag signal, such that the NMOS transistor conducts.

In some embodiments, the source (S electrode) of the NMOS transistor 204 is grounded, and the drain (D electrode) is connected with the flag lead 201 and the pull-up resistor 205. The NMOS transistor 204 is configured to pull the flag lead 201 down to a low level when conducting.

The flag lead 201 transmits signals to the host when pulled down to a low level.

In some embodiments, the first terminal of the pull-up resistor 205 is connected with the flag lead 201 and the NMOS transistor 204, and the second terminal is connected with the power supply inside the micro-display panel. The pull-up resistor 205 is configured to pull the flag lead 201 to a high level when the NMOS transistor 204 is not conducting.

In some embodiments, the ratio of the resistance value of the pull-up resistor to the equivalent resistance value of the NMOS transistor 204 is set such that the difference between the high level and low level of the flag lead is less than or equal to 50% of the high level. By adjusting the ratio between the pull-up resistor and the equivalent resistance of the NMOS transistor 204, the level transition of the flag lead is relatively gradual, which is conductive to improving the stability and reliability of the circuit.

In some embodiments, the pull-up resistor 205 is a weak pull-up resistor of 1kΩ to 500kΩ.

In some embodiments, the register 206 is connected with the pull-up resistor 205, and the register 206 controls the state of the pull-up resistor 205, i.e., controlling the turn-on and -off of the register 206. The register sends an enable signal (PD_EN) to the pull-up resistor 205, the pull-up resistor 205 conducts, and the pull-up resistor 205 enables to pull the level of the flag lead 201 connected with it to a high level.

In the default state, the NMOS transistor 204 is not conducting, the pull-up resistor 205 is enabled, and the state of the flag lead 201 is controlled by the pull-up resistor 205, and the flag lead 201 is at a high level.

When the host 100 requires a certain micro-display panel to return a certain flag signal, the host 100 sends a turn-on instruction to the certain control signal generation module of this micro-display panel through the communication interface, and after receiving the turn-on instruction, this control signal generation module outputs a high level control signal, i.e., the control signal is 1. When the corresponding event has occurred within the micro-display panel, the flag signal generation module outputs a high level flag signal, i.e., the flag signal is 1, and the AND gate module output a high level. The OR gate module (the first OR gate module or the second OR gate module) connected with this AND gate module outputs a high level, and the third OR gate module 503 outputs a high level. After receiving the high level signal, the gate of the NMOS transistor 204 connected with the output terminal of the third OR gate module 503 meets the gate voltage condition for conduction, so that the NMOS transistor 204 enters the conductive state. A low-resistance path is formed between the drain and source of the NMOS transistor 204 (the turn-on resistance is typically very small). The flag lead 201 is grounded through the conducting NMOS transistor 204, so that the electrical potential of the flag lead 201 is rapidly pulled down, and becomes a low electrical potential. For the host, since it is connected with the flag lead 201, the input terminal of the host 100 can detect the low level signal, and thus identify that the corresponding event has occurred. If the flag lead 201 is in a high level state, it indicates that no related event has occurred.

Taking the return row scan timing flag signal as an example, the return process of the flag signal is described in detail below.

After receiving the turn-on instruction from the host, the first control signal generation module outputs a high level first control signal. The high level first control signal is input to the first AND gate module 401, and when the row scan timing flag signal is a low level, the first AND gate module 401 outputs a high level, and the first OR gate module 501 outputs a high level; since the first OR gate module 501 is connected with the first input terminal of the third OR gate module 503, the third OR gate module 503 also outputs a high level. The output terminal of the third OR gate module 503 is connected with the gate of the NMOS transistor 204, and the NMOS transistor conducts. The conducting NMOS transistor 204 pulls the level of the flag lead 201 down, and the flag lead 201 becomes a low level state, and the host 100 detects the low level signal and thereby identifies the corresponding event has occurred, i.e., the micro-display panel has scanned to a designated row in row scan mode.

When the first control signal is in a low level state, the first AND gate module 401 will not output a high level regardless of whether the row scan timing flag signal is in a high level state.

The micro-display panel is described in detail below.

In some embodiments, the micro-display panel includes micro-LED chips configured to emit light; the micro-LED chip includes a drive backplane; and a plurality of micro-LEDs arranged in an array on the drive backplane.

In some embodiments, the micro-display panel further includes a circuit board electrically connected with the micro-LED chip. The circuit board may include a flexible circuit board and/or a rigid circuit board. The circuit board has an external interface, and the external interface is configured to connect to an external power source and/or control commands to power the micro-LED chip and/or control the micro-LED chip.

In some embodiments, the range of the length and width of the light-emitting area of the micro-LED chip is several millimeters to one hundred micrometers, and the light-emitting area includes a plurality of micro-LEDs arranged in an array.

The micro-LED structures are formed in the form of an array in the micro-LED chip, and with resolutions such as 720*480, 640*480, 1920*1080, 1280*720, 2K, or 4K. The diameters of the micro-LED structures are in the nanometer-level, for example, 20 nm to 100 nm.

In some embodiments, the micro-LED array may include a single layer of micro-LED structures. In some embodiments of the present disclosure, the pitch of the micro-LED array, i.e., the minimum center-to-center distance between micro-LEDs, may be between approximately 2 micrometers and approximately 50 micrometers. In some embodiments, the number of pixels on the micro-LED chip may be between thousands and millions.

In some embodiments, the micro-LEDs may be arranged in a regular or irregular manner on the drive backplane as pixels of the micro-LED chip.

In some embodiments, the drive backplane may be electrically connected with each micro-LED in the micro-LED array through individual metal interconnections. In some embodiments, each micro-LED may be individually electrically controlled by the drive backplane. In some embodiments, the drive backplane may be electrically connected with electrodes of the micro-LED chip through metal interconnections. In some embodiments, the drive backplane is an IC backplane.

In some embodiments, the drive backplane includes a substrate, a drive circuit, and drive electrodes. The drive circuit is located in the substrate and controls the turning-on and -off of the micro-LEDs; the drive electrodes are located in the substrate with at least the upper surfaces exposed, and the drive electrodes are electrically connected with the drive circuit. Each micro-LED corresponds to a drive electrode, and the micro-LEDs are located on the drive electrodes and electrically connected with the drive electrodes.

In some embodiments, the material of the drive electrodes is an alloy of one or more of the following metals: Ni, Al, Ti, Cu, Pt, and Au. In some embodiments, the substrate is a Si substrate. In other embodiments, the substrate is a transparent substrate, such as a glass substrate. Other substrate examples include GaAs, GaP, InP, SiC, ZnO, and sapphire substrates. In some embodiments, the substrate is approximately 700 micrometers thick. The drive circuit forms individual pixel drivers to control the operation of each individual pixel LED device. The drive circuit may, for example, include complementary metal oxide semiconductor (CMOS) devices or thin-film transistor (TFT) devices. In some embodiments, a dielectric layer may be formed in the gaps between the micro-LEDs. In some embodiments, the dielectric layer may also be formed in the gaps between interconnections.

The drive method of the micro-LEDs is, for example, a passive matrix (PM) drive, and the cathodes of all micro-LEDs of each array are connected together to a cathode line NL, while micro-LEDs of the same number of each array are connected to corresponding anode lines PL, respectively. Thus, the on/off and brightness of each LED can be individually controlled by controlling the signal on the corresponding cathode and anode.

In some embodiments, the micro-LEDs may be bonded to the surface of the drive backplane through a bonding layer. The drive electrodes are electrically connected with the bonding layer, and the bonding layer includes a first metal layer and a second metal layer. In some embodiments, the material of the first metal layer is an alloy of one or more of the following metals: Cr, Al, Ti, Ni, Pt, Au, and Sn; and/or the material of the second metal layer is an alloy of one or more of the following metals: Cr, Al, Ti, Ni, Pt, Au, and Sn.

In some embodiments, the micro-LED includes: an epitaxial layer, an ohmic contact layer, a top conductive layer, and a passivation isolation layer. The ohmic contact layer is located on the bonding layer and is electrically connected with the bonding layer. The epitaxial layer is arranged on the ohmic contact layer. The passivation isolation layer at least partially covers the side surface of the epitaxial layer, and the passivation isolation layer is located between the epitaxial layer and the top conductive layer. The top conductive layer is located on the side surface and top surface of the epitaxial layer.

In some embodiments, the material of the passivation isolation layer is, for example, a solid inorganic material or a plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. The passivation isolation layer is transparent to light emitted from the epitaxial layer.

In some embodiments, the first metal layer of the bonding layer directly contacts the ohmic contact layer at the bottom of the epitaxial layer, and the second metal layer is located at the bottom layer of the bonding layer and away from the epitaxial layer, and the contour of the first metal layer is less than the contour of the second metal layer.

In some embodiments, the transverse dimension at the bottom of the epitaxial layer is greater than the transverse dimension at the top. In some embodiments, the light-emitting mesa is a step shape or a trapezoid shape.

In some embodiments, the epitaxial layer is a trapezoid shape, but is not limited to a normally arranged trapezoid or an upside-down arranged trapezoid. In some embodiments, the range of the inclination angle of the sidewall of the epitaxial layer is 60° to 85°. In one embodiment, the transverse dimension of the bonding layer is greater than the transverse dimension of the bottom of the epitaxial layer.

In some embodiments, the epitaxial layer includes a first type epitaxial layer, a second type epitaxial layer, and a light-emitting layer positioned between them. The first type epitaxial layer is located above the light-emitting layer, away from the drive backplane, while the second type epitaxial layer is positioned below the light-emitting layer, close to the drive backplane.

In some embodiments, the light-emitting layer is formed by multiple stacked quantum well layers, particularly superlattice-stacked quantum well layers. Preferably, the superlattice-stacked quantum well layers include multiple pairs of quantum well layers stacked with quantum barrier layers.

In one embodiment, the light-emitting layer includes a multi-quantum-well layer and an electron blocking layer, and the multi-quantum-well layer is an InGaN/GaN multi-quantum-well layer or an InGaN/AlGaN multi-quantum-well layer or an InGaAs/AlGaAs multi-quantum-well layer. In another embodiment, the first type epitaxial layer may also be a P-type GaN layer or a P-type AlGaN layer, while the second type epitaxial layer is an N-type GaN layer or an N-type AlGaN layer.

In some embodiments, the first type epitaxial layer is a semiconductor material with a first type epitaxial layer and includes a plurality of semiconductor layers. The primary matrix material of the first type epitaxial layer may be, but is not limited to at least two or more elements of Ga, N, As, P, In, and Al. Furthermore, the first type epitaxial layer may include, from top to bottom, but is not limited to, a confinement layer and a waveguide layer; furthermore, in some embodiments, an ohmic contact layer may be formed on the confinement layer.

In some embodiments, the second type epitaxial layer is a semiconductor material with a second conductivity type and includes a plurality of semiconductor layers. The primary matrix material of the second type epitaxial layer may be, but is not limited to, materials such as Ga, N, As, P, In, or Al, etc. Furthermore, the second type epitaxial layer may include, from top to bottom, but is not limited to, a waveguide layer, a confinement layer, a transition layer, and a window layer; furthermore, an ohmic contact layer may be formed below the window layer.

In some embodiments, the first type epitaxial layer is an N-type GaN layer or an N-type AlGaN layer, and the second type epitaxial layer is a P-type GaN layer or a P-type AlGaN layer, i.e., the material of the second type epitaxial layer is a material layer of a second conductivity type including at least two or more elements of Ga, N, As, Al, In, and P, and the first type epitaxial layer is a material layer of a first conductivity type including at least two or more elements of Ga, N, As, Al, In, and P.

In some embodiments, the light-emitting layer includes at least one quantum well layer. The thickness of the quantum well layer is between 20 nm and 40 nm, for example, the thickness is 30 nm. In some embodiments, the material of the quantum well layer is GaInP/(AlₓGa₁₋ₓ)_{y}In_{1-y}P, and the range of x is 0.5 to 0.9, and the range of y is 0.3 to 0.5. For example, x is 0.8 and y is 0.5. In some embodiments, the relationship between x and y is that x is 1 to 2 times y. In some embodiments, the light-emitting layer is a multi-quantum well (MQW).

In some embodiments, one of the first type epitaxial layer and the second type epitaxial layer is an N-type semiconductor layer, and the other is a P-type semiconductor layer. In some embodiments, the N-type semiconductor layer also includes a doped N-type contact layer and an N-type cladding layer. The N-type cladding layer is formed on the doped N-type contact layer. The material of the N-type cladding layer is AlₓIn₁₋ₓP, and the range of x is 0.1 to 0.5, for example, x is 0.5. Furthermore, in these embodiments, the thickness of the N-type cladding layer is no greater than 350 nm, for example, the thickness of the N-type cladding layer is 320 nm. The doping concentration of the N-type cladding layer is 5e¹⁷cm⁻³ to 1e¹⁸cm⁻³. In some embodiments, the N-type semiconductor layer also includes a doped N-type contact layer and an N-type cladding layer formed on the doped N-type contact layer. The material of the doped N-type contact layer is GaAs. In some embodiments, the thickness of the doped N-type contact layer is 10 nm to 30 nm. In some embodiments, the doping concentration of the doped N-type contact layer is 2e¹⁸cm⁻³ to 1e¹⁹cm⁻³. In some embodiments, the N-type semiconductor layer also includes an N-type spacer layer formed on the N-type cladding layer. The material of the N-type spacer layer is (AlₓGa₁₋ₓ)_{y}In_{1-y}P, and the range of x is 0.5 to 0.9, and the range of y is 0.1 to 0.5. For example, x is 0.8 and y is 0.5. In some embodiments, the relationship between x and y is that x is 1 to 2 times y. The thickness of the N-type spacer layer is 50 nm to 75 nm, for example, 65 nm. In some embodiments, the P-type semiconductor layer includes a P-type cladding layer and a doped P-type contact layer. The P-type cladding layer is formed on the light-emitting layer, and the doped P-type contact layer is formed on the P-type cladding layer.

In some embodiments, the material of the P-type cladding layer is AlₓIn₁₋ₓP, and x is 0.3 to 0.5, for example, x is 0.5. In such embodiments, the thickness of the P-type cladding layer is no greater than 380 nm, for example, the thickness of the P-type cladding layer is 360 nm.

In some embodiments, the material of the doped P-type contact layer is GaAs. The thickness of the doped P-type contact layer is 10 nm to 30 nm, for example, 20 nm.

In some embodiments, the P-type semiconductor layer also includes a P-type spacer layer formed below the P-type cladding layer, a first doped P-type transition layer formed on the P-type cladding layer, and a second doped P-type transition layer formed on the first doped P-type transition layer. In some embodiments, the material of the P-type spacer layer is (AlₓGa₁₋ₓ)_{y}In_{1-y}P, and the range of x is 0.5 to 0.9, and the range of y is 0.3 to 0.5. For example, x is 0.8 and y is 0.5. In some embodiments, the relationship between x and y is that x is 1 to 2 times y. In some embodiments, the thickness of the P-type spacer layer is 50 nm to 75 nm, for example, 65 nm.

In some embodiments, the material of the first doped P-type transition layer is (AlₓGa₁₋ₓ)_{y}In_{1-y}P, and the range of x is 0.1 to 0.3, and the range of y is 0.3 to 0.5. For example, x is 0.17 and y is 0.5. In some embodiments, the relationship between x and y is that y is 1 to 5 times x. In some implementations, the thickness of the first doped P-type transition layer is 20 nm to 40 nm, for example, 30 nm.

In some embodiments, the material of the second doped P-type transition layer is AlₓGa₁₋ₓAs, and the range of x is 0.5 to 0.9, for example, x is 0.6. In some embodiments, the thickness of the second doped P-type transition layer is 10 nm to 30 nm, for example, 20 nm.

In some embodiments, the doping concentration of the second doped P-type transition layer is greater than the doping concentration of the first doped P-type transition layer. The doping concentration of the doped P-type contact layer is 1 to 10 times the doping concentration of the second doped P-type transition layer.

In some embodiments, the doping concentration of the doped P-type contact layer is greater than the doping concentration of the second doped P-type transition layer. Furthermore, in some embodiments, the doping concentration of the second doped P-type transition layer is 2 to 4 times the doping concentration of the first doped P-type transition layer.

For example, the doping concentration of the first doped P-type transition layer is greater than 1e¹⁸cm⁻³, the doping concentration of the second doped P-type transition layer is in the range of 2e¹⁸cm⁻³ to 4e¹⁸cm⁻³, and the doping concentration of the doped P-type contact layer is greater than 5e¹⁸cm⁻³. In some embodiments, the electrode polarity of the ohmic contact layer is opposite to the electrode polarity of the top conductive layer, the ohmic contact layer may be, for example, a P electrode or an anode electrode, and the top conductive layer is an electrode with opposite polarity to the ohmic contact layer, for example, an N electrode or a cathode electrode. In one embodiment, the ohmic contact layer, the top conductive layer, and their connecting components may be a combination of one or more of, such as graphene, or indium tin oxide (ITO), or aluminum-doped zinc oxide (AZO), or fluorine-doped tin oxide (FTO), or other transparent conductive oxides (TCOs).

In one embodiment, adjacent top conductive layers are connected, and all top conductive layers are connected as a whole. In some embodiments, the top conductive layer may be shared by all micro-LEDs in a micro-LED array.

In some embodiments, the electrode polarity of the ohmic contact layer is opposite to the electrode polarity of the top conductive layer, the ohmic contact layer may be, for example, a P electrode or an anode electrode, and the top conductive layer is an electrode with opposite polarity to the ohmic contact layer, for example, an N electrode or a cathode electrode. In one embodiment, the ohmic contact layer, the top conductive layer, and their connecting components may be a combination of one or more of, such as graphene, or indium tin oxide (ITO), or aluminum-doped zinc oxide (AZO), or fluorine-doped tin oxide (FTO), or other transparent conductive oxides (TCOs).

In some embodiments, adjacent passivation isolation layers are connected, and all passivation isolation layers are connected as a whole. In one embodiment, the material of the passivation isolation layer is one or more of silicon oxide, silicon oxynitride, aluminum oxide, and silicon nitride.

In some embodiments, the micro-LED chip further includes a current expansion structure located between the micro-LEDs, and the current expansion structure is arranged to surround the micro-LEDs, and the current expansion structure is configured to electrically contact the micro-LEDs and at least partially reflect light emitted by the micro-LEDs.

The current expansion structure surrounds the micro-LEDs, and the current expansion structure is electrically connected with the micro-LEDs.

The surface of the current expansion structure facing the micro-LEDs has light reflection ability, for example, it is made of metal, so that the current expansion structure can at least partially reflect the light emitted by the LED. The reflection process is that: the light emitted from the light-emitting layer of the LED passes through the transparent layer (e.g., the top conductive layer) above it, and then a first part of this light (whose exit angle is small enough not to touch the current expansion structure on the side surface, within a preset exit angle, such as ±20°) directly exits, the second part of this light (whose exit angle is large enough to touch the current expansion structure on the side surface) touches the current expansion structure and is reflected, and then exits with a changed optical path direction within the preset exit angle, thereby effectively improving the light extraction efficiency. Preferably, the proportion of light reflected by the current expansion structure to the light emitted by the LED can be, for example, 10% to 60%. By arranging a current expansion structure with light reflection ability, the amount of light absorbed by the sidewall can be significantly reduced, thereby significantly increasing the total light output. Meanwhile, the current expansion structure can also isolate light and prevent light crosstalk between adjacent LEDs.

By arranging the current expansion structure to surround the top conductive layer of the micro-LED in an electrical contact manner, the electrical contact area between the current expansion structure and the micro-LED can be significantly increased, thereby enabling the active layer (light-emitting layer) of the micro-LED to emit light more uniformly, so that higher brightness of light emission only at the electrical contact area or near the electrical contact area is effectively avoided.

The bottom dimensions of the current expansion structure are larger than its top dimensions. Since the bottoms of adjacent current expansion structures are connected, the longitudinal cross-section of two adjacent current expansion structures exhibits a bifurcated peak shape.

The bottoms of adjacent current expansion structures are connected, and all current expansion structures are connected as a whole. For the micro-LED with a circular top view shape (i.e. cross-sectional shape), the top view shape of the overall current expansion structure is the remaining grid shape after removing the circular shape. In other embodiments, the top view shape of the micro-LED may also be other appropriate shapes, such as rectangle, square, or regular polygon, etc. The top view shape of the overall current expansion structure may also be the shape remaining after removing other appropriate shapes, such as the remaining grid shape after removing rectangles, squares, or polygons.

In embodiments of the present disclosure, the bottom of the current expansion structure is lower than the epitaxial layer of the micro-LED.

In embodiments of the present disclosure, the top of the current expansion structure may be higher than the top of the epitaxial layer; the top of the current expansion structure may also be flush with the top of the epitaxial layer; the top of the current expansion structure may also be lower than the top of the epitaxial layer (e.g., slightly lower than the top of the epitaxial layer by 0-1 micrometers). One, two, or three of the above situations may coexist in a chip.

Preferably, the top of the current expansion structure is higher than the top of the epitaxial layer of the micro-LED, and by making the height of the top of the current expansion structure greater than the height of the top plane of the epitaxial layer of the micro-LED, a higher current expansion structure can be achieved, and the opportunity of light reflection is further improved and the light extraction efficiency is increased.

In other embodiments, the number of current expansion structures may also be 1/4 or 1/9 of the number of micro-LEDs, and each current expansion structure surrounds 4 micro-LEDs or 9 micro-LEDs, without limitation.

The current expansion structure can increase current expansion between adjacent micro-LEDs, and reduce resistance between adjacent micro-LEDs, and minimize losses. The current expansion structure can rapidly and uniformly spread current to all micro-LEDs.

In embodiments of the present disclosure, the current expansion structure may be a multi-layer structure, and the current expansion structure includes one or more main metal layers. In embodiments of the present disclosure, the material of the main metal layer may be one or more of Pt, Au, Al, or Ag.

In some embodiments, the current expansion structure may further include: isolation layers corresponding one-to-one with each main metal layer; and the isolation layers are arranged alternately with the main metal layers, and each main metal layer is located on a corresponding isolation layer.

By using isolation layers corresponding one-to-one with each main metal layer and arranging the isolation layers alternately with the main metal layers, and positioning each main metal layer on a corresponding isolation layer, the influence of electromigration within the current expansion structure can be effectively suppressed by arranging isolation layers, and particularly in the case of high density of the micro-LEDs in a micro-LED display chip, by arranging isolation layers, the possibility of increasing the height of the current spread structure is obtained, so that the light extraction efficiency is further improved through a higher current expansion structure. Furthermore, the isolation layers may include titanium (Ti) metal layers. It should be noted that the materials of the isolation layers may also include other suitable materials, such as titanium nitride (TiN).

In some embodiments, the current expansion structure may further include: an adhesive layer located at the bottommost layer of the current expansion structure, and the isolation layers and main metal layers are located above the adhesive layer. The adhesive layer is formed between the micro-LEDs, and the isolation layers and main metal layers are located above the adhesive layer, the bottom stability of the current expansion structure can be effectively improved through the adhesive effect of the adhesive layer, and particularly in the case of high density of the micro-LEDs in a micro-LED display chip, by arranging the adhesive layer, the possibility of increasing the height of the current spread structure can be obtained, so that the light extraction efficiency is further improved through a higher current expansion structure. Furthermore, the adhesive layer may include a chromium (Cr) metal layer. It should be noted that the adhesive layer material may also include other suitable materials, such as one or more of the following: titanium (Ti), titanium nitride (TiN), or tungsten (W).

In embodiments of the present disclosure, the current expansion structure may further include: anti-diffusion layers corresponding one-to-one with the isolation layers, and each isolation layer is located above the corresponding anti-diffusion layer. By forming anti-diffusion layers corresponding one-to-one with the isolation layers, and locating each isolation layer above the corresponding anti-diffusion layer, the stability of the current expansion structure can be improved through the high hardness and excellent corrosion resistance characteristics of the anti-diffusion layers, and particularly in the case of high density of the micro-LEDs in a micro-LED display chip, by arranging anti-diffusion layers, the possibility of increasing the height of the current spread structure can be obtained, so that the light extraction efficiency is further improved through a higher current expansion structure. The anti-diffusion layers may include: platinum (Pt) metal layers, nickel (Ni) metal layers. It should be noted that the anti-diffusion layers may be a single-layer platinum metal layer, may also be a single-layer nickel metal layer, and may also be a stacked layer of single-layer platinum metal layer and single-layer nickel metal layer.

In some embodiments, the micro-LED chip further includes a micro-lens array. The micro-lens array is arranged above the micro-LED array, and at least one micro-lens is provided on the surface of the conductive layer at the top of the micro-LED, and the horizontal contour of the micro-lens is larger than the maximum horizontal contour of the micro-LED. The microlens primarily serves to converge and/or collimate light, for example, by adjusting parameters such as the thickness and curvature of the microlens, etc., the focal point of the microlens can be located in the epitaxial layer of the micro-LED. In some embodiments, microlenses in the microlens array correspond one-to-one with the epitaxial layers. In some embodiments, examples of microlenses include spherical microlenses, non-spherical microlenses, Fresnel microlenses, and cylindrical microlenses.

In embodiments of the present disclosure, adjacent microlenses have gaps between them. In embodiments of the present disclosure, the bottoms of the gaps are higher than the top of the epitaxial layer. In another embodiment of the present disclosure, the bottoms of the gaps are lower than the top of the epitaxial layer but higher than the bottom of the epitaxial layer. In yet another embodiment of the present disclosure, the bottoms of the gaps are located above the current expansion structure. Specifically, the gaps are located between two adjacent current expansion structures (i.e., between the bifurcation peaks).

Furthermore, the microlenses may also have air gaps inside. Each microlens may have a plurality of air gaps, and the size and length of each air gap is the same or different. Meanwhile, in the same chip, the number of air gaps and/or position and/or size of air gaps in different microlenses may be the same or different. In some embodiments of the present disclosure, the air gaps are located at the edge of the microlens, specifically, they may be, for example, located on two sides of the epitaxial layer, preferably, they are located between the epitaxial layer and the current expansion structure. Meanwhile, in some embodiments, the tops of the air gaps are higher than the top of the epitaxial layer, and the bottoms of the air gaps may be higher than the top of the epitaxial layer, and may also be lower than the top of the epitaxial layer. In some embodiments, the bottoms of the air gaps are higher than the top of the current expansion structure. In other embodiments, the bottoms of the air gaps are lower than the top of the current expansion structure. It should be noted that in other embodiments of the present disclosure, the microlenses may also not have an air gap inside.

In some embodiments, the micro-LED chip includes a light-emitting area and a non-light-emitting area, and the aforementioned micro-LEDs, current expansion structure, and microlens array are located in the light-emitting area. The non-light-emitting area surrounds the light-emitting area.

In some embodiments, the non-light-emitting area of the micro-LED chip has bonding wire electrodes, and the bonding wire electrodes are electrically connected with the drive backplane. The bonding wire electrodes are used for electrical connection with the circuit board outside the chip.

Although some embodiments of the present disclosure have been described in the present application, those skilled in the art will appreciate that these embodiments are merely illustrated as examples. Numerous variation schemes, alternative schemes, and improvement schemes may be conceived by those skilled in the art in light of the teachings of the present disclosure without departing from the scope of the present disclosure. The appended claims are intended to define the scope of the present disclosure and thus encompass methods and structures within the scope of these claims themselves and their equivalent variations.

What is claimed is:

1. A micro-display system, comprising:
a plurality of micro-display panels, each comprising:
a flag lead configured to transmit signals to a host when the flag lead is driven to a high level;
a PMOS transistor connected with the flag lead, wherein the PMOS transistor is configured to drive the flag lead to the high level when the PMOS transistor is conducting;
a pull-down resistor having a first terminal connected with the flag lead and a second terminal grounded, wherein the pull-down resistor is configured to pull the flag lead down to a low level when the PMOS transistor is not conducting; and
a signal circuit module connected with the PMOS transistor and configured to generate a high level control signal when receiving a turn-on instruction from the host, and to send a low level signal to the PMOS transistor when generating a flag signal, such that the PMOS transistor conducts; and
a shared transmission line connecting the host with the flag leads of the plurality of micro-display panels.

2. The micro-display system according to claim 1, wherein the PMOS transistor has a source connected with a power supply inside each of the plurality of micro-display panels, a drain connected with the flag lead, and a gate connected with the signal circuit module.

3. The micro-display system according to claim 2, wherein the drain of the PMOS transistor is further connected with the pull-down resistor.

4. The micro-display system according to claim 2, wherein the signal circuit module comprises:
a flag signal input terminal; and
an inverter connected between the flag signal input terminal and the PMOS transistor.

5. The micro-display system according to claim 4, wherein the flag signal input terminal comprises:
a plurality of flag signal generation modules configured to generate flag signals;
a plurality of control signal generation modules configured to generate control signals to control whether the flag signals generated by the flag signal generation modules are output;
a plurality of AND gate modules, wherein input terminals of the plurality of AND gate modules are connected with at least one flag signal generation module and at least one control signal generation module; and
an OR gate module group having an input terminal connected with the output terminals of the plurality of AND gate modules and an output terminal connected with the inverter.

6. The micro-display system according to claim 5, wherein the plurality of flag signal generation modules comprise: a row scan timing flag signal generation module, a first global scan timing flag signal generation module, a second global scan timing flag signal generation module, a DSI processing module interrupt signal generation module, and a DSI interrupt signal generation module; and
the plurality of control signal generation modules comprise a first control signal generation module, a second control signal generation module, a third control signal generation module, a fourth control signal generation module, and a fifth control signal generation module.

7. The micro-display system according to claim 6, wherein the plurality of AND gate modules comprise a first AND gate module, a second AND gate module, a third AND gate module, a fourth AND gate module, and a fifth AND gate module, wherein:
the first input terminal of the first AND gate module is connected with the row scan timing flag signal generation module, and the second input terminal of the first AND gate module is connected with the first control signal generation module;
the first input terminal of the second AND gate module is connected with the first global scan timing flag signal generation module, and the second input terminal of the second AND gate module is connected with the second control signal generation module;
the first input terminal of the third AND gate module is connected with the second global scan timing flag signal generation module, and the second input terminal of the third AND gate module is connected with the third control signal generation module;
the first input terminal of the fourth AND gate module is connected with the DSI processing module interrupt signal generation module, and the second input terminal of the fourth AND gate module is connected with the third control signal generation module; and
the first input terminal of the fifth AND gate module is connected with the DSI interrupt signal generation module, and the second input terminal of the fifth AND gate module is connected with the third control signal generation module.

8. The micro-display system according to claim 1, wherein the shared transmission line has one end connected with a lead of the host and another end connected with the flag leads of the plurality of micro-display panels.

9. The micro-display system according to claim 1, wherein the ratio of the resistance value of the pull-down resistor to the equivalent resistance value of the PMOS transistor is set such that the difference between the high level and low level of the flag lead is less than or equal to 50% of the high level.

10. A micro-display system, comprising:
a plurality of micro-display panels, each comprising:
a flag lead configured to transmit signals to a host when the flag lead is pulled down to a low level;
an NMOS transistor connected with the flag lead, wherein the NMOS transistor is configured to pull the flag lead down to the low level when the NMOS transistor is conducting;
a pull-up resistor having a first terminal connected with the flag lead and a second terminal connected with a power supply inside each of the plurality of micro-display panels, wherein the pull-up resistor is configured to pull the flag lead up to a high level when the NMOS transistor is not conducting; and
a flag signal input terminal connected with the NMOS transistor and configured to generate a high level control signal when receiving a turn-on instruction from the host, and to send a high level signal to the NMOS transistor when generating a flag signal, such that the NMOS transistor conducts; and
a shared transmission line connecting the host with the flag leads of the plurality of micro-display panels.

11. The micro-display system according to claim 10, wherein the NMOS transistor has a source grounded, a drain connected with the flag lead, and a gate connected with the flag signal input terminal.

12. The micro-display system according to claim 11, wherein the drain of the NMOS transistor is further connected with the pull-up resistor.

13. The micro-display system according to claim 11, wherein the flag signal input terminal comprises:
a plurality of flag signal generation modules configured to generate flag signals;
a plurality of control signal generation modules configured to generate control signals to control whether the flag signals generated by the flag signal generation modules are output;
a plurality of AND gate modules, wherein input terminals of the plurality of AND gate modules are connected with at least one flag signal generation module and at least one control signal generation module; and
an OR gate module group having an input terminal connected with the output terminals of the plurality of AND gate modules and an output terminal connected with the gate of the NMOS transistor.

14. The micro-display system according to claim 13, wherein the plurality of flag signal generation modules comprise: a row scan timing flag signal generation module, a first global scan timing flag signal generation module, a second global scan timing flag signal generation module, a DSI processing module interrupt signal generation module, and a DSI interrupt signal generation module; and
the plurality of control signal generation modules comprise a first control signal generation module, a second control signal generation module, a third control signal generation module, a fourth control signal generation module, and a fifth control signal generation module.

15. The micro-display system according to claim 14, wherein the plurality of AND gate modules comprise a first AND gate module, a second AND gate module, a third AND gate module, a fourth AND gate module, and a fifth AND gate module, wherein:
the first input terminal of the first AND gate module is connected with the row scan timing flag signal generation module, and the second input terminal of the first AND gate module is connected with the first control signal generation module;
the first input terminal of the second AND gate module is connected with the first global scan timing flag signal generation module, and the second input terminal of the second AND gate module is connected with the second control signal generation module;
the first input terminal of the third AND gate module is connected with the second global scan timing flag signal generation module, and the second input terminal of the third AND gate module is connected with the third control signal generation module;
the first input terminal of the fourth AND gate module is connected with the DSI processing module interrupt signal generation module, and the second input terminal of the fourth AND gate module is connected with the third control signal generation module; and
the first input terminal of the fifth AND gate module is connected with the DSI interrupt signal generation module, and the second input terminal of the fifth AND gate module is connected with the third control signal generation module.

16. The micro-display system according to claim 10, wherein the shared transmission line has one end connected with a lead of the host and another end connected with the flag leads of the plurality of micro-display panels.

17. The micro-display system according to claim 10, wherein the ratio of the resistance value of the pull-up resistor to the equivalent resistance value of the NMOS transistor is set such that the difference between the high level and low level of the flag lead is less than or equal to 50% of the high level.

18. A weak pull-up/pull-down circuit, comprising:
an MOS transistor having a gate connected with a flag signal input terminal, wherein a first electrode selected from a drain and a source of the MOS transistor is connected with a first voltage source, and a second electrode selected from the drain and the source is connected with a first terminal of a pull-up/pull-down resistor;
a pull-up/pull-down resistor having a second terminal connected to a second voltage source, wherein the pull-up/pull-down resistor is configured to be turned on and off by a register signal; and
a flag lead connected with the second electrode of the MOS transistor and the first terminal of the pull-up/pull-down resistor.

19. The weak pull-up/pull-down circuit according to claim 18, wherein the ratio of the resistance value of the pull-up/pull-down resistor to the equivalent resistance value of the MOS transistor is set such that the difference between the high level and low level of the flag lead is less than or equal to 50% of the high level.

20. A micro-display panel, comprising the weak pull-up/pull-down circuit according to claim 18.
